(19) United States
(12) Patent Application Publication
(10) Pub. No.: US 2017/0088417 A1
(43) Pub. Date: Mar. 30, 2017

(54) ELECTRONIC DEVICE AND MANUFACTURING METHOD THEREOF

(71) Applicant: XINTEC INC., Taoyuan City (TW)

(72) Inventors: Yu-Chen LAI, Su'ao Township (TW); Meng-Han KUO, Taipei City (TW); Ming-Chieh HUANG, Kaohsiung City (TW); Hsi-Chien LIN, Zhubei City (TW)

(21) Appl. No.: 15/275,693

(22) Filed: Sep. 26, 2016

Related U.S. Application Data
(60) Provisional application No. 62/234,465, filed on Sep. 29, 2015.

(51) Int. Cl. B81C 1/00; B81B 7/00; H01L 27/146

(52) U.S. Cl. CPC B81C 1/00246; H01L 27/146; B81B 7/0022; B81C 1/00269; B81C 2203/0714

(57) ABSTRACT

An electronic device includes an image sensor that has a device layer and a MEMS device that is located on the image sensor and includes a MEMS element, a cap element, and a cover layer. The MEMS element having plural hollow regions is located on the device layer, such that a first cavity is formed between the MEMS element and the image sensor. The cap element having an opening is located on a surface of the MEMS element facing away from the device layer, such that a second cavity is formed between the cap element and the MEMS element and communicates with the opening. The first cavity communicates with the second cavity through the hollow regions. The cover layer is located on a surface of the cap element facing away from the MEMS element and is located in the opening of the cap element.

### RELATED APPLICATIONS

This application claims priority to U.S. provisional Application Ser. No. 62/234,465, filed Sep. 29, 2015, which is herein incorporated by reference.

### BACKGROUND

Field of Invention

The present invention relates to an electronic device and a manufacturing method of the electronic device.

Description of Related Art

With the development of science and technology, electronic products are required to have more functions. In order to meet the requirements of multi-functions for an electronic product, different semiconductor chips and electrical components have to be disposed on a printed circuit board of the electronic product. However, when the number of the components is desired to be increased, the volume of the electronic product has to be increased, and thus the electronic product fails to satisfy product miniaturization requirements. In order to meet the product miniaturization requirements, in general, a semiconductor chip and a micro electro mechanical system (MEMS) device may be integrated as an electronic device with the MEMS device. As a result, not only the space for accommodating the printed circuit board can be reduced for further reducing the volume of the electronic product, but also the electronic product can retain its multi-functions.

After the MEMS device and the semiconductor chip are combined, a cavity is formed between the MEMS device and the semiconductor chip, and the cavity is in a vacuum state. The electrical component (e.g., an accelerometer or a gyroscope) of the MEMS device is corresponding to the cavity in position. However, when the cavity is in a vacuum state, the electrical component may not have good performance. Because the process capability is limited, pressure in the cavity between the MEMS device and the semiconductor chip cannot be adjusted and controlled. For example, an accelerometer in a 1 atm environment has better performance than in a vacuum environment.

### SUMMARY

An aspect of the present invention is to provide an electronic device.

According to an embodiment of the present invention, an electronic device includes an image sensor and a MEMS device. The image sensor has a device layer. The MEMS device is located on the image sensor and includes a MEMS element, a cap element, and a cover layer. The MEMS element is located on the device layer, such that a first cavity is formed between the MEMS element and the image sensor. The MEMS element has plural hollow regions. The cap element is located on a surface of the MEMS element facing away from the device layer, such that a second cavity is formed between the cap element and the MEMS element. The cap element has an opening that communicates with the second cavity. The first cavity communicates with the second cavity through the hollow regions. The cover layer is located on a surface of the cap element facing away from the MEMS element and is located in the opening of the cap element.

Another aspect of the present invention is to provide a manufacturing method of an electronic device.

According to an embodiment of the present invention, a manufacturing method of an electronic device includes the following steps. A cap element is bonded to a MEMS element to form a MEMS device. The MEMS device is bonded to an image sensor, and a first cavity between the MEMS element and the image sensor communicates with a second cavity between the cap element and the MEMS element through hollow regions of the MEMS element. An opening is formed in the cap element, and the opening communicates with the second cavity. A cover layer is formed on a surface of the cap element facing away from the MEMS element and in the opening of the cap element.

In the aforementioned embodiment of the present invention, because the cap element has the opening that communicates with the second cavity and the first cavity communicates with the second cavity through the hollow regions, the first and second cavities may communicate with outside of the electronic device after the opening of the cap element is formed and before the cover layer is formed. Hence, the pressure of each of the first cavity and the second cavity is increased to about 1 atm from a vacuum state. After the cover layer is formed in the opening of the cap element, the pressure of the first cavity and the second cavity may be maintained about 1 atm. As a result, the performance for some electrical components (e.g., an accelerometer) in the cap element may be improved.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiments, with reference made to the accompanying drawings as follows:

FIG. 1 is a cross-sectional view of an electronic device according to one embodiment of the present invention;

FIG. 2 is a flow chart of a manufacturing method of an electronic device according to one embodiment of the present invention;

FIG. 3 is a cross-sectional view of an electronic device according to one embodiment of the present invention;

FIG. 4 is a cross-sectional view of an electronic device according to one embodiment of the present invention; and

FIG. 5 is a cross-sectional view of an electronic device according to one embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

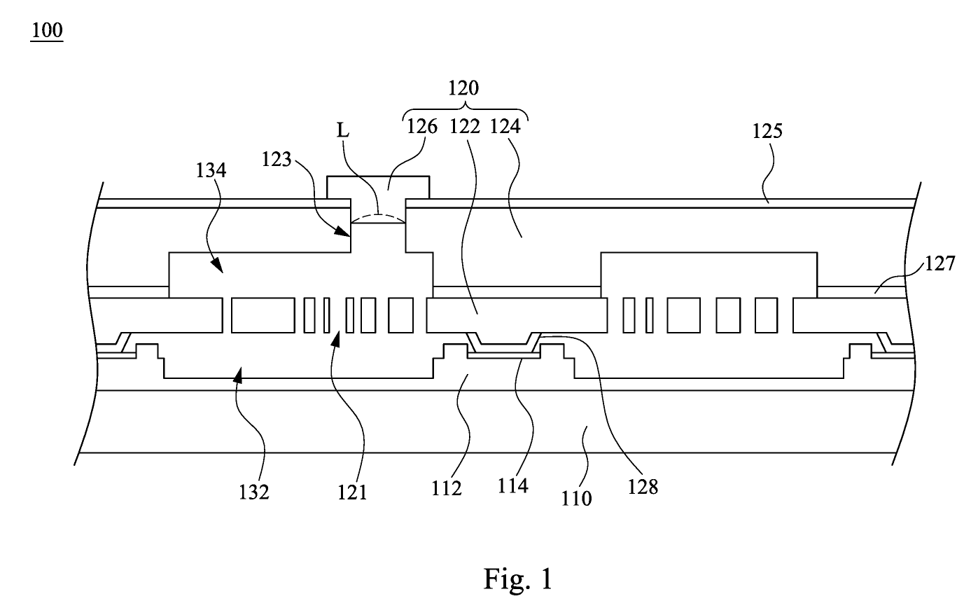

FIG. 1 is a cross-sectional view of an electronic device 100 according to one embodiment of the present invention. As shown in FIG. 1, the electronic device 100 includes an image sensor 110 and a micro electro mechanical system (MEMS) device 120. The image sensor 110 has a device layer 112. The MEMS device 120 is located on the image sensor 110 and includes a MEMS element 122, a cap element 124, and a cover layer 126. The MEMS element 122 is located on the device layer 112 of the image sensor 110, such that a first cavity 132 is formed between the MEMS element 122 and the image sensor 110. Moreover, the MEMS element 122 has plural hollow regions 121, such that the MEMS element 122 is formed in a comb shape. When detecting the potential difference across a capacitance, the MEMS element 122 can have good sensitivity due to its comb shape, thereby improving the calculation accuracy of the image sensor 110.

The cap element 124 is located on a surface of the MEMS element 122 facing away from the device layer 112, such that a second cavity 134 is formed between the cap element 124 and the MEMS element 122. The first cavity 132 communicates with the second cavity 134 through the hollow regions 121 of the MEMS element 122. The cap element 124 has an opening 123 that communicates with the second cavity 134. The cover layer 126 is located on a surface of the cap element 124 facing away from the MEMS element 122 and is located in the opening 123 of the cap element 124.

In this embodiment, the cover layer 126 may be a solder mask, but the present invention is not limited in this regard. The cap element 124 may include an accelerometer, a gyroscope, or a combination thereof. For example, in FIG. 1, the cap element 124 at the left side of the opening 123 of the cap element 124 may be an accelerometer, and the cap element 124 at the right side of the opening 123 of the cap element 124 may be a gyroscope. However, in another embodiment, the cap element 124 may include other components that have other functions, and the present invention is not limited in this regard.

Since the cap element 124 has the opening 123 that communicates with the second cavity 134 and the first cavity 132 communicates with the second cavity 134 through the hollow regions 121 of the MEMS element 122, the first and second cavities 132, 134 may communicate with outside of the electronic device 100 after the opening 123 of the cap element 124 is formed and before the cover layer 126 is formed. Hence, the pressure of each of the first cavity 132 and the second cavity 134 is increased to about 1 atmosphere (atm) from a vacuum state. After the cover layer 126 is formed in the opening 123 of the cap element 124, the pressure of the first cavity 132 and the second cavity 134 may be maintained at about 1 atm. In this text, the term “about” may refer to a variation of 10% from an indicated value. As a result, the performance for some electrical components (e.g., an accelerometer) in the cap element 124 may be improved.

In another embodiment, after the opening 123 of the cap element 124 is formed, the pressure of the first cavity 132 and the second cavity 134 may be controlled and adjusted through the opening 123 of the cap element 124, for example, by withdrawing air out or pumping air in. After the adjustment of the pressure is completed, the cover layer 126 is formed to block the opening 123, such that the first cavity 132 and the second cavity 134 maintain an adjusted pressure. In other words, in the electronic device 100 of the present invention, designers may adjust and control the pressure of the first cavity 132 and the second cavity 134 in accordance with the type of the electrical component of the cap element 124 to improve the performance of the electrical component of the cap element 124.

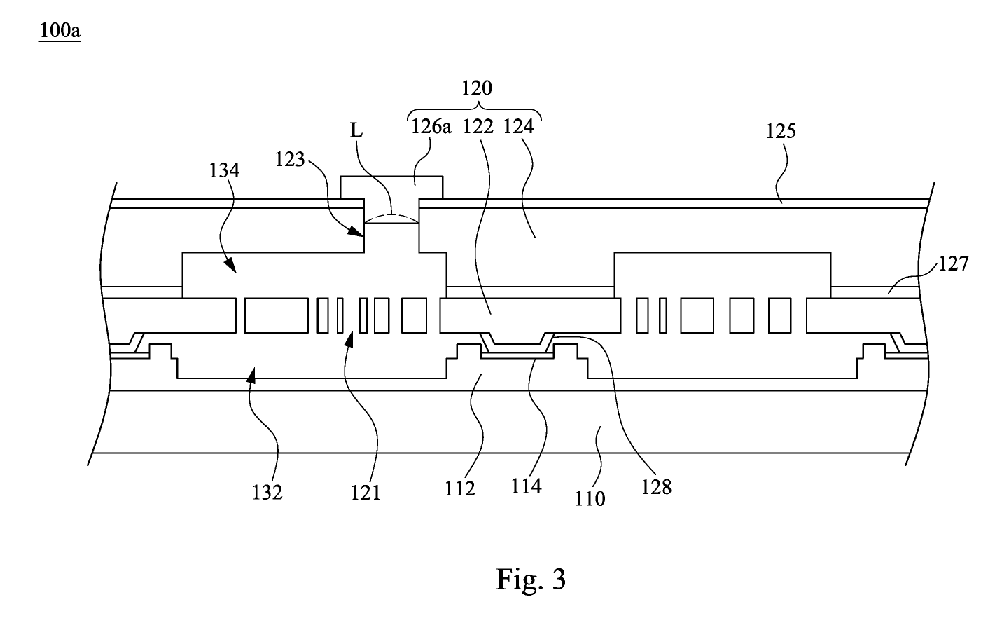

The cover layer 126 in the opening 123 of the cap element 124 has a bottom surface that faces the second cavity 134. The bottom surface of the cover layer 126 may be a flat surface (as shown by a solid-line bottom surface of FIG. 1) or a curved surface L (as shown by a dotted-line bottom surface of FIG. 1), and the present invention is not limited in this regard. The cover layer 126 may form the curved surface L due to the material of the cover layer 126 (such as a solder mask) or a pressure variation of a manufacturing process. In addition, in other embodiments, such as electronic devices 100a, 100b, and 100c respectively shown in FIGS. 3, 4, and 5, each of the cover layers 126 and 126a may also have the curved surface L, which will not be described again in the following description.

In this embodiment, the cap element 124 further includes a static electricity eliminating layer 125 that is located on the surface of the cap element 124 facing away from the MEMS element 122. The static electricity eliminating layer 125 may be used for grounding to eliminate the static electricity of the electronic device 100. The static electricity eliminating layer 125 may be made of a material including an aluminum-copper alloy, but the present invention is not limited in this regard.

Furthermore, the image sensor 110 has a first bonding layer 114, and the first bonding layer 114 is located on a surface of the device layer 112 facing the MEMS element 122. The MEMS element 122 has a second bonding layer 128 that is electrically connected to the first bonding layer 114. In this embodiment, the first bonding layer 114 may be made of a material including aluminum, and the second bonding layer 128 may be made of a material including germanium, but the present invention is not limited in this regard. In addition, the MEMS device 120 may further include an isolation layer 127 that is disposed between the MEMS element 122 and the cap element 124.

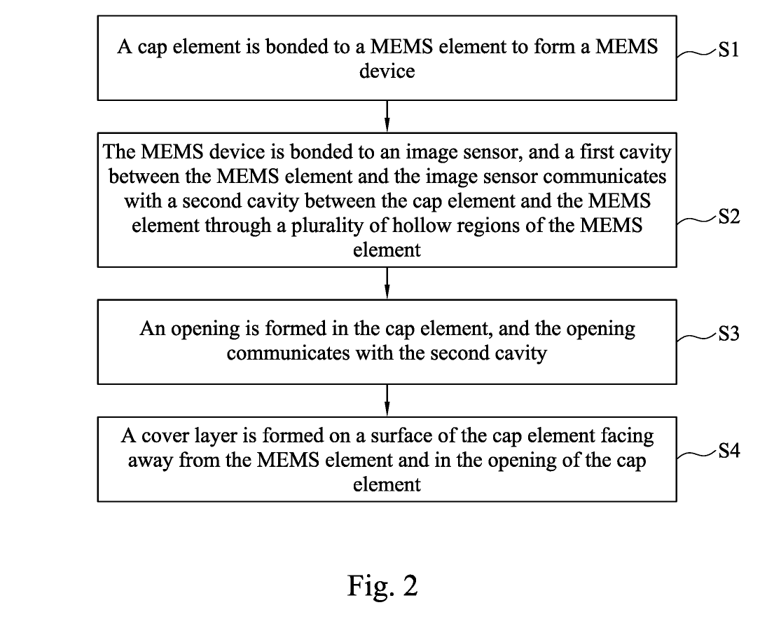

FIG. 2 is a flow chart of a manufacturing method of an electronic device according to one embodiment of the present invention. The manufacturing method of the electronic device includes the following steps. In step S1, a cap element is bonded to a MEMS element to form a MEMS device. Thereafter, in step S2, the MEMS device is bonded to an image sensor, and a first cavity between the MEMS element and the image sensor communicates with a second cavity between the cap element and the MEMS element through a plurality of hollow regions of the MEMS element. Afterwards, in step S3, an opening is formed in the cap element, and the opening communicates with the second cavity. Subsequently, in step S4, a cover layer is formed on a surface of the cap element facing away from the MEMS element and in the opening of the cap element.

Moreover, the manufacturing method of the electronic device may further include forming a static electricity eliminating layer on the surface of the cap element facing away from the MEMS element.

Through the aforementioned manufacturing method, the electronic device 100 shown in FIG. 1 can be obtained.

It is noted that the connection relationships and the materials of the aforementioned elements will not be described again in the following description. In the following description, other types of electronic devices will be described.

FIG. 3 is a cross-sectional view of an electronic device 100a according to one embodiment of the present invention. The electronic device 100a includes the image sensor 110 and the MEMS device 120. The image sensor 110 has the device layer 112. The MEMS device 120 is located on the image sensor 110 and includes the MEMS element 122, the cap element 124, and a cover layer 126a. The difference between this embodiment and the embodiment shown in FIG. 1 is that the cover layer 126a of the MEMS device 120 of the electronic device 100a is an adhesive, but not a solder mask. As a result of such a design, the cover layer 126a formed in the opening 123 of the cap element 124 may be used to maintain the specific pressure of the first cavity 132 and the second cavity 134 (such as 1 atm).

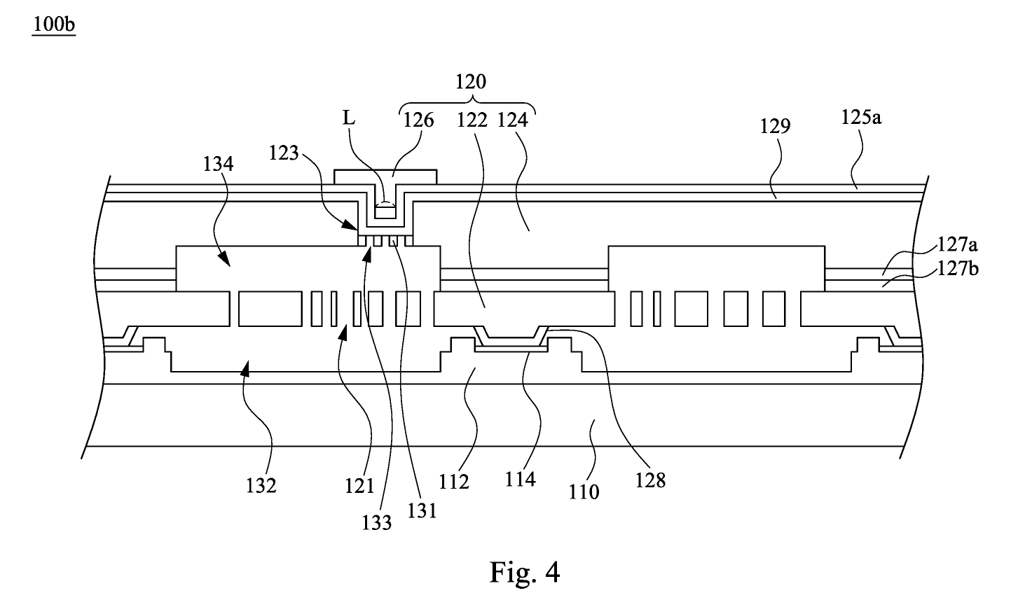

FIG. 4 is a cross-sectional view of an electronic device 100b according to one embodiment of the present invention. The electronic device 100b includes the image sensor 110 and the MEMS device 120. The image sensor 110 has the device layer 112. The MEMS device 120 is located on the image sensor 110 and includes the MEMS element 122, the cap element 124, and the cover layer 126. The difference between this embodiment and the embodiment shown in FIG. 1 is that the cap element 124 of the MEMS device 120 of the electronic device 100b further includes a stop layer 131 and an isolation layer 129, and the MEMS device 120 of the electronic device 100b includes two stacked isolation layers 127a, 127b.

The stop layer 131 is located in the opening 123 of the cap element 124 and has through holes 133. After the opening 123 of the cap element 124 is formed and before the cover layer 126 is formed, although the stop layer 131 is present between the second cavity 134 and the opening 123 of the cap element 124, the first cavity 132 and second cavity 134 may still communicate with outside of the electronic device 100b through the through holes 133 of the stop layer 131, such that users may adjust and control the pressure of the first and second cavities 132, 134. In addition, in this embodiment, the cover layer 126 is a solder mask. The isolation layer 129 is located on the surface of the cap element 124 facing away from the MEMS element 122, a sidewall of the cap element 124 surrounding the opening 123, and the stop layer 131. A static electricity eliminating layer 125a is located on the isolation layer 129. The static electricity eliminating layer 125a may be made of a material including an aluminum-copper alloy. The stop layer 131 may provide a supporting force to the isolation layer 129 and the static electricity eliminating layer 125a, such that the isolation layer 129 and the static electricity eliminating layer 125a may extend into the opening 123.

The manufacturing method of the electronic device 100b further includes the following steps beside steps S1-S4 of FIG. 2. An isolation layer is formed on the surface of the cap element facing away from the MEMS element, a sidewall of the cap element surrounding the opening, and the stop layer. A static electricity eliminating layer is formed on the isolation layer.

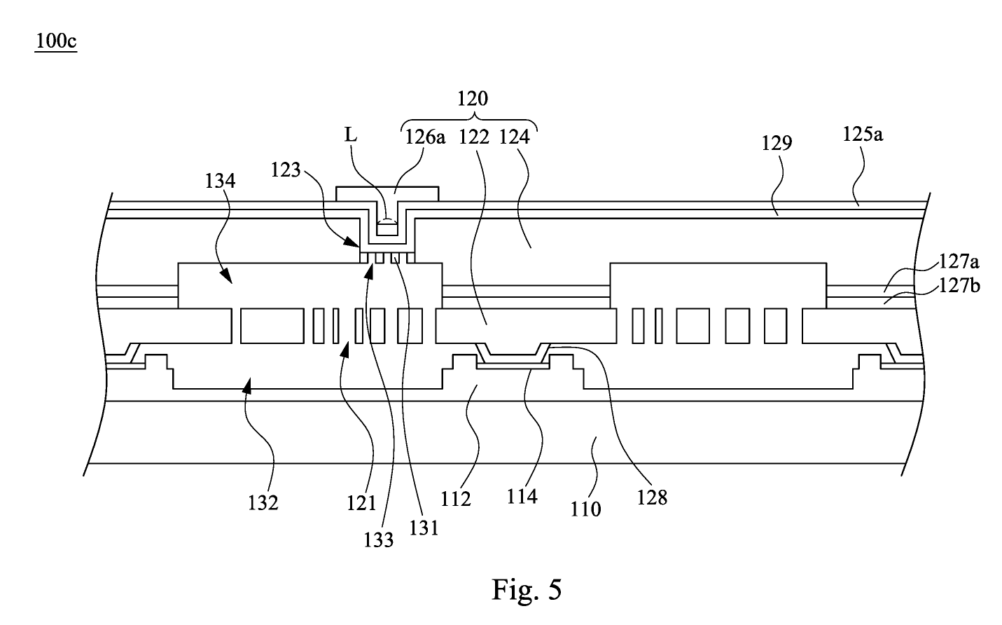

FIG. 5 is a cross-sectional view of an electronic device 100c according to one embodiment of the present invention. The electronic device 100c includes the image sensor 110 and the MEMS device 120. The image sensor 110 has the device layer 112. The MEMS device 120 is located on the image sensor 110 and includes the MEMS element 122, the cap element 124, and the cover layer 126a. The difference between this embodiment and the embodiment shown in FIG. 4 is that the cover layer 126a of the MEMS device 120 of the electronic device 100c is an adhesive, but not a solder mask. As a result of such a design, the cover layer 126a formed in the opening 123 of the cap element 124 may be used to keep the specific pressure of the first cavity 132 and the second cavity 134 (such as 1 atm).

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims.

What is claimed is:

1. An electronic device, comprising:
an image sensor having a device layer; and
a micro electro mechanical system (MEMS) device located on the image sensor, the MEMS including:
a MEMS element located on the device layer, such that a first cavity is formed between the MEMS element and the image sensor, wherein the MEMS element has a plurality of hollow regions;
a cap element located on a surface of the MEMS element facing away from the device layer, such that a second cavity is formed between the cap element and the MEMS element, wherein the cap element has an opening that communicates with the second cavity, and the first cavity communicates with the second cavity through the hollow regions; and
a cover layer that is located on a surface of the cap element facing away from the MEMS element and is located in the opening of the cap element.

2. The electronic device of claim 1, wherein the cover layer is a solder mask or an adhesive.

3. The electronic device of claim 1, wherein the cap element further comprises:
a static electricity eliminating layer located on the surface of the cap element facing away from the MEMS element.

4. The electronic device of claim 3, wherein the static electricity eliminating layer is made of a material comprising an aluminum-copper alloy.

5. The electronic device of claim 1, wherein the cap element further comprises:
a stop layer located in the opening of the cap element, the stop layer having a plurality of through holes.

6. The electronic device of claim 5, wherein the cap element further comprises:
an isolation layer located on the surface of the cap element facing away from the MEMS element, a sidewall of the cap element surrounding the opening, and the stop layer.

7. The electronic device of claim 6, wherein the cap element further comprises:
a static electricity eliminating layer located on the isolation layer.

8. The electronic device of claim 7, wherein the static electricity eliminating layer is made of a material comprising an aluminum-copper alloy.

9. The electronic device of claim 1, wherein the image sensor has a first bonding layer that is located on a surface of the device layer facing the MEMS element; the MEMS element has a second bonding layer that is electrically connected to the first bonding layer.

10. The electronic device of claim 1, wherein the MEMS device further comprises:
at least one isolation layer disposed between the MEMS element and the cap element.

11. The electronic device of claim 1, wherein the cap element comprises an accelerometer, a gyroscope, or a combination thereof.

12. The electronic device of claim 1, wherein the MEMS element is comb-shaped.

13. The electronic device of claim 1, wherein a pressure of each of the first cavity and the second cavity is 1 atm.

14. The electronic device of claim 1, wherein the cover layer in the opening of the cap element has a curved surface that faces the second cavity.

15. A manufacturing method of an electronic device, the manufacturing method comprising:
bonding a cap element to a MEMS element to form a MEMS device;
bonding the MEMS device to an image sensor, wherein a first cavity between the MEMS element and the image sensor communicates with a second cavity between the cap element and the MEMS element through a plurality of hollow regions of the MEMS element;
forming an opening in the cap element, wherein the opening communicates with the second cavity; and
forming a cover layer on a surface of the cap element facing away from the MEMS element and in the opening of the cap element.

16. The manufacturing method of claim 15, further comprising:
forming a static electricity eliminating layer on the surface of the cap element facing away from the MEMS element.

17. The manufacturing method of claim 15, wherein the cap element further comprises a stop layer that is located in the opening of the cap element and has a plurality of through holes, and the manufacturing method further comprises:
forming an isolation layer on the surface of the cap element facing away from the MEMS element, on a sidewall of the cap element surrounding the opening, and on the stop layer.

18. The manufacturing method of claim 17, further comprising:
forming a static electricity eliminating layer on the isolation layer.
